(19) United States
(12) Patent Application Publication
(10) Pub. No.: US 2014/0151860 A1
(43) Pub. Date: Jun. 5, 2014

(54) WIRELESS MODULE

(71) Applicant: Panasonic Corporation, Osaka (JP)

(72) Inventors: Toshiaki Nakamura, Nara (JP); Suguru Fujita, Tokyo (JP); Maki Nakamura, Kanagawa (JP); Ryosuke Shiozaki, Kanagawa (JP); Jun'ichi Kimura, Osaka (JP); Hirokazu Kitamura, Osaka (JP)

(21) Appl. No.: 14/131,548

(22) PCT Filed: Feb. 1, 2013
(86) PCT No.: PCT/JP2013/000578

§ 371 Date: Jan. 8, 2014

(30) Foreign Application Priority Data
Feb. 15, 2012 (JP) 2012-030896
Feb. 16, 2012 (JP) 2012-032186
Feb. 16, 2012 (JP) 2012-032187

(51) Int. Cl. H01L 23/66

(52) U.S. Cl. CPC H01L 23/66
USPC 257/664

(57) ABSTRACT

A wireless module includes a first board which has a first component mounted thereon, a second board which faces the first board and has a second component mounted thereon, a connecting member which is provided between the first board and the second board and transmits a signal between the first board and the second board, and a filling material with which a space between the first board and the second board including the connecting member is sealed. A conductive member for connecting a ground between the first board and the second board is arranged in a periphery of the connecting member.

### TECHNICAL FIELD

The present disclosure relates to a wireless module which is used in wireless communication and has an electronic component mounted on a board.

### BACKGROUND ART

In a related art, as the configuration of a circuit module for wireless communication which has an electronic circuit mounted on a board, a configuration is known, in which a board having an active device (for example, an IC (Integrated Circuit)) mounted thereon and a board having a passive device (for example, a resistor, an inductor, or a capacitor) mounted thereon are arranged to face each other and electrically connected together, and the space between the boards is sealed with resin.

For example, Patent Literature 1 discloses a semiconductor apparatus as a wireless module which uses a board having an antenna as a passive device mounted thereon and a board having a semiconductor device as an active device mounted thereon.

In the semiconductor apparatus of Patent Literature 1, an antenna is mounted on one surface of a silicon board, a semiconductor device as an active device is mounted on the other surface of the silicon board, and the antenna and the semiconductor device are electrically connected together through a through-via passing through the silicon board. A passive device is mounted on one surface of a wiring board formed separately from the silicon board, and the wiring board and the silicon board are electrically connected together through a connecting member provided between one surface of the wiring board and the other surface of the silicon board.

As the configuration of the wireless module of the related art, a configuration is also known, in which a first board having an active device and a passive device mounted thereon and a second board having an antenna mounted thereon are arranged to face each other, and the two boards are electrically connected together by a connecting member. In the wireless module having the configuration of the related art, a semiconductor device (for example, an IC) as the active device and a chip capacitor or a chip resistor as the passive device are mounted on the first board, and the connecting member (for example, a solder-plated Cu (copper) core solder ball) is mounted on the second board.

The mounting surfaces of the first board and the second board are arranged to face each other, the solder of the connecting member is molten and electrically connected to the first board, and mold resin (filling material) as seal resin is filled in a buried layer having a component between the boards to seal the space between the boards with resin. Accordingly, a wireless module in which a plurality of boards are laminated is realized.

### CITATION LIST

### Patent Literature

Patent Literature 1: JP-a-2009-266979

### SUMMARY OF INVENTION

### Technical Problem

In the wireless module of the related art, in wireless communication using a high frequency including millimeter waves, a signal is easily radiated from a signal line provided between the first board and the second board.

The present disclosure has been accomplished in consideration of the situation of the related art, and provides a wireless module which reduces a radiation loss of a signal radiated from a transmission line in wireless communication using a high frequency including millimeter waves.

### Solution to Problem

A wireless module according to an aspect of the present disclosure includes: a first board which has a first component mounted thereon; a second board which faces the first board and has a second component mounted thereon; a connecting member which is provided between the first board and the second board, and transmits a signal between the first board and the second board; a filling material with which a space between the first board and the second board including the connecting member is sealed; and a conductive member, arranged in a periphery of the connecting member, for connecting a ground between the first board and the second board.

### Advantageous Effects of Invention

According to the present disclosure, it is possible to reduce a radiation loss of a signal radiated from a transmission line in wireless communication using a high frequency including millimeter waves.

### BRIEF DESCRIPTION OF DRAWINGS

FIG. 1 is a cross-sectional view showing the internal structure of a wireless module according to a first embodiment.

FIG. 2 is a plan view showing a lower board and an upper board, and specifically, (A) is a plan view of the lower board when a wireless module is viewed in perspective view from the top to the bottom of FIG. 1, and (B) is a plan view of the upper board when a wireless module is viewed from the top to the bottom of FIG. 1.

FIG. 3 is a graph showing antenna performance corresponding to a frequency for each number of patches.

FIG. 4 is a graph showing a simulation result of change in transmission loss corresponding to a frequency for each number of ground copper core solder balls.

In FIG. 5, (A) to (C) are plan views showing an example of the arrangement relationship between one signal copper core solder ball and three ground copper core solder balls.

In FIG. 6, (A) and (B) are cross-sectional views taken along the line A-A′ of (A) to (C) in FIG. 5.

In FIG. 7, (A) to (C) are plan views showing an example of the arrangement relationship between one signal copper core solder ball and two ground copper core solder balls.

In FIG. 8, (A) is a plan view showing an example of the arrangement relationship between one signal copper core solder ball and three ground copper core solder balls, and (B) and (C) are plan views showing an example of the arrangement relationship between two signal copper core solder balls and three ground copper core solder balls.

FIG. 9 is a plan view showing an example of the arrangement relationship between two signal copper core solder balls and two ground copper core solder balls.

FIG. 10 is a cross-sectional view showing the internal structure of a wireless module according to a second embodiment.

FIG. 11 is a perspective view showing various conductive members, and specifically, (A) shows a conductive member having a tubular quadrangular frame, (B) shows a U-shaped conductive member, and (C) shows a cylindrical conductive member.

FIG. 12 is a perspective view showing the structure of a coaxial member according to a third embodiment, and specifically, (A) shows a coaxial member having a cubic body portion, and (B) shows a coaxial member having a cylindrical body portion.

FIG. 13 is a cross-sectional view showing the internal structure of a wireless module according to a fourth embodiment.

FIG. 14 is an enlarged view of a soldering location of a copper core ball connected between an upper board and a lower board.

In FIG. 15, (A) and (B) are diagrams showing behavior of a solder when soldering is performed.

In FIG. 16, (A), (B) and (C) are diagrams showing behavior of a solder during soldering of the related art.

FIG. 17 is a diagram showing an image of a transmission line along a copper core ball between an upper board and a lower board, and specifically, (A) shows the image when uniform, and (B) shows the image when not uniform.

FIG. 18 is a cross-sectional view showing a structure example of a wireless module according to a fifth embodiment.

In FIG. 19, (A) and (B) are plan views showing a configuration example of a lower board and an upper board according to the fifth embodiment.

In FIG. 20, (A) to (C) are diagrams showing an arrangement example of a rib provided in the periphery of a patch of an antenna according to the fifth embodiment.

FIG. 21 is a plan view showing an example of an upper board of a wireless module according to a sixth embodiment.

In FIG. 22, (A) to (C) are diagrams showing an arrangement example of a rib according to the sixth embodiment.

In FIG. 23, (A) and (B) are diagrams showing a configuration example of a wireless module according to a seventh embodiment.

### DESCRIPTION OF EMBODIMENTS

Hereinafter, embodiments of the present disclosure will be described referring to the drawings.

(Background to an Aspect of the Present Disclosure)

In the wireless module of the related art, the gap between the first board and the second board is small to be about 0.4 mm at maximum. In a frequency domain using a wavelength of equal to or greater than 1 cm (for example, 5 cm), the ratio of the gap and the wavelength is negligibly small, and even if impedance discontinuity occurs, there is no critical problem.

In contrast, for example, in a frequency domain of millimeter waves, the ratio of the gap (a maximum of 0.4 mm) between the first board and the second board and the wavelength (for example, 5 mm) is not negligibly small. For this reason, when impedance discontinuity occurs, a radiation loss of a signal from a transmission line disposed between the first board and the second board increases. For this reason, in wireless communication, the amount of power consumption in the wireless module increases.

In the wireless module of the related art, a copper core solder ball for connecting a ground between the first board and the second board is arranged without taking into consideration the transmission line between the first board and the second board. For this reason, in particular, in wireless communication of millimeter waves, a signal is easily radiated from the signal line disposed between the first board and the second board.

In the following embodiments, a wireless module which reduces a radiation loss of a signal radiated from a transmission line in wireless communication using a high frequency including millimeter waves will be described.

A wireless module of each embodiment is used in a wireless communication of a high frequency (for example, 60 GHz) in a millimeter-wave band, and has electronic components (for example, an antenna and a semiconductor device) mounted thereon.

### First Embodiment

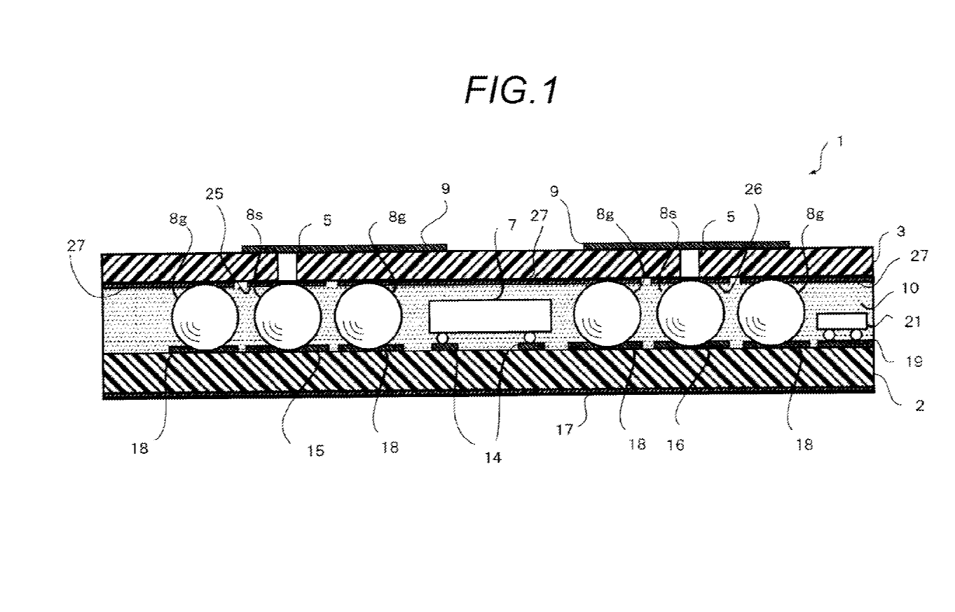

FIG. 1 is a cross-sectional view showing the internal structure of a wireless module 1 according to a first embodiment. FIG. 1 shows a cross-section of the wireless module 1 when viewed laterally. The wireless module 1 is mounted on a set board (not shown) which has various electronic components mounted thereon, and includes a second board (lower board) 2 as a main board and a first board (upper board) 3 as a sub-board facing the set board.

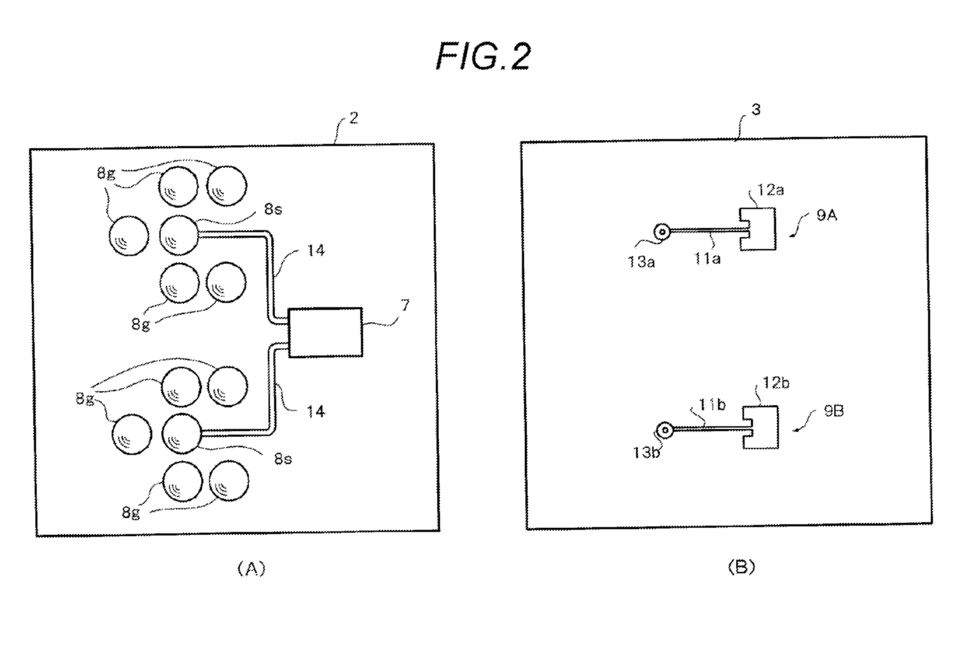

FIGS. 2(A) and 2(B) are plan views showing the lower board 2 and the upper board 3. FIG. 2(A) is a plan view of the lower board 2 when the wireless module 1 is viewed in perspective view from the top to the bottom of FIG. 1. FIG. 2(B) is a plan view of the upper board 3 when the wireless module 1 is viewed from the top to the bottom of FIG. 1.

In FIG. 1, the lower board 2 is formed using, for example, an insulating material of a dielectric having a dielectric constant of about 3 to 4, and has a single layer structure. The lower board 2 is not limited to the single layer structure, and may have a multilayer structure having a plurality of layers. On one surface (upper surface) of the lower board 2, wiring patterns 14 having a semiconductor device 7 (second component) as an electronic component mounted thereon and wiring pads 15 and 16 electrically connected to the wiring patterns 14 are formed. Copper core solder balls 8s (connecting member) for signal transmission which electrically connect the semiconductor device (for example, an IC) 7 and the upper board 3 are soldered to the wiring pads 15 and 16. The copper core solder balls 8s for signal transmission are conductive spheres.

On the upper surface of the lower board 2, ground patterns 18 are formed so as to surround the wiring pads 15 and 16. Five ground copper core solder balls 8g are soldered to the ground patterns 18 so as to surround the copper core solder balls 8s for signal transmission (see FIG. 2(A)). The ground copper core solder balls 8g are conductive spheres.

On the upper surface of the lower board 2, a wiring pattern 19 is formed, and a passive device (for example, a chip capacitor or a chip resistor) 21 as an electronic component is mounted through the wiring pattern 19. On the lower surface of the lower board 2, a sheet-like copper foil ground pattern 17 is formed.

In FIG. 1, the upper board 3 is formed using, for example, an insulating material of a dielectric having a dielectric constant of about 3 to 4, and has a single layer structure. The upper board 3 is not limited to the single layer structure, and may have a multilayer structure having a plurality of layers. On the lower surface of the upper board 3, wiring pads 25 and 26 for electrically connecting the copper core solder balls 8s for signal transmission, and sheet-like copper foil ground patterns 27 are formed.

The copper core solder balls 8s are respectively soldered to the wiring pads 25 and 26. The wiring pads 25 and 26 and the ground patterns 27 are not electrically connected together.

On the upper surface of the upper board 3, signal pads 13a and 13b (see FIG. 2(B)) electrically connected to the wiring pads 25 and 26 through through-vias 5, feed lines 11a and 11b respectively connected to the signal pads 13a and 13b, and pad-like copper foil antennas 9A and 9B (first components) respectively connected to the feed lines 11a and 11b are formed. The antennas 9A and 9B are, for example, patch antennas. In the following description, the antennas 9A and 9B are collectively referred to as “antennas 9” when there is no need for distinction between the antennas 9A and 9B”.

In this embodiment, the antennas 9A and 9B respectively have single patches 12a and 12b (see FIG. 2(B)). The antennas 9A and 9B may respectively have a plurality of patches, for example, four patches.

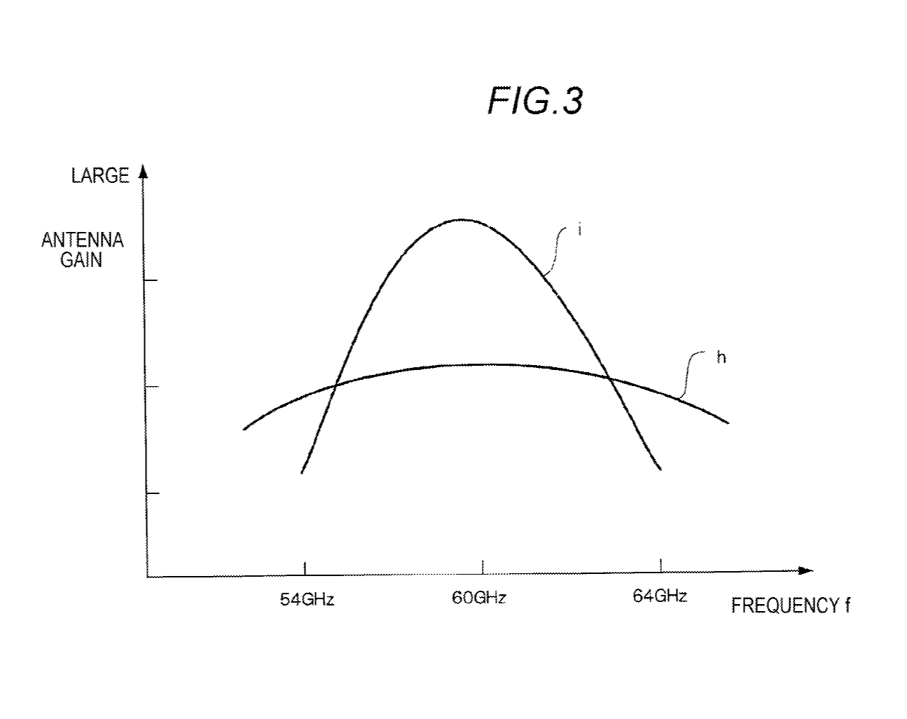

FIG. 3 is a graph showing antenna performance corresponding to a frequency for each number of patches. In the wireless module 1 of this embodiment, as indicated by a solid line h, the antenna has a single patch, and the gain of the antenna spreads centering on 60 GHz. That is, when the antenna has a single patch, the gain of the antenna does not greatly change depending on a frequency. In contrast, when the antenna has four patches, as indicated by a solid line i, the gain of the antenna is sharpened with 60 GHz as a peak.

A buried layer between the lower board 2 and the upper board 3 in which the copper core solder balls 8s for signal transmission, the ground copper core solder balls 8g, the semiconductor device 7, and a passive device 21 are provided is filled with, for example, a filling material 10 of mold resin and sealed.

The diameters of the copper core solder balls 8s and 8g are determined according to the height of an electronic component (for example, the semiconductor device 7) mounted in the buried layer between the lower board 2 and the upper board 3, and is, for example, 200 μm. In this case, the diameter of the wiring pads 15 and 16 is greater than the diameter of the copper core solder balls 8s and 8g, and becomes, for example, 300 μm.

In this way, in the wireless module 1, the lower board 2 and the upper board 3 are arranged to face each other, and are electrically connected together through the copper core solder balls 8s soldered between the wiring pad 15 and the wiring pad 25 and between the wiring pad 16 and the wiring pad 26. The copper core solder balls 8s become a signal transmission path between the semiconductor device 7 (a part of a wireless circuit) mounted on the lower board 2 and the antennas 9 mounted on the upper board 3.

In FIG. 2(A), the ground copper core solder balls 8g soldered between the ground patterns 18 and the ground patterns 27, for example, five ground copper core solder balls 8g are arranged at positions surrounding each of a pair of copper core solder balls 8s as the transmission path. In this way, the copper core solder balls 8s for signal transmission are surrounded by the ground copper core solder balls 8g, whereby the periphery of the transmission path can be grounded (GND). Accordingly, the wireless module 1 of this embodiment suppresses radiation of a signal from the copper core solder ball 8s for signal transmission as the transmission path, thereby reducing a transmission loss (radiation loss).

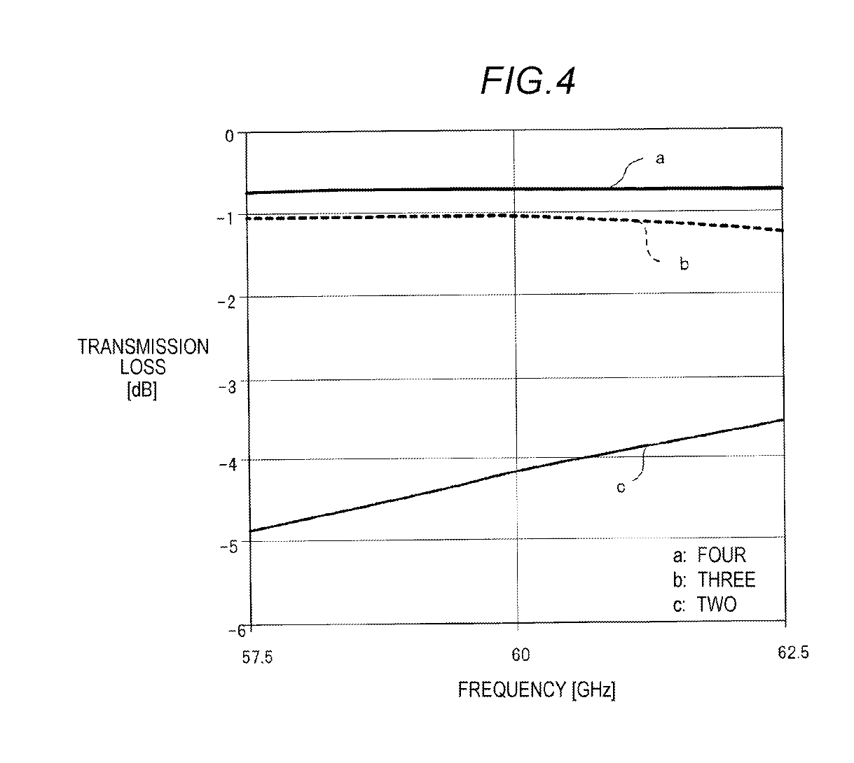

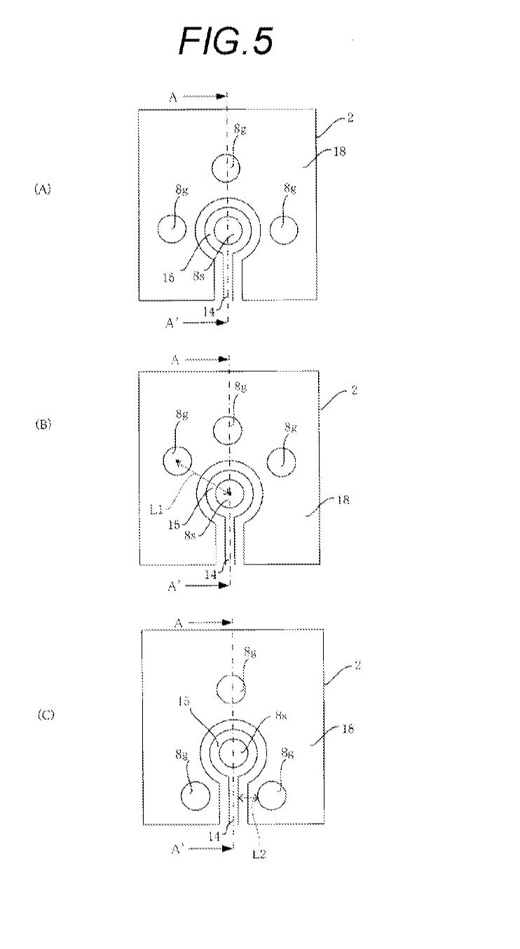

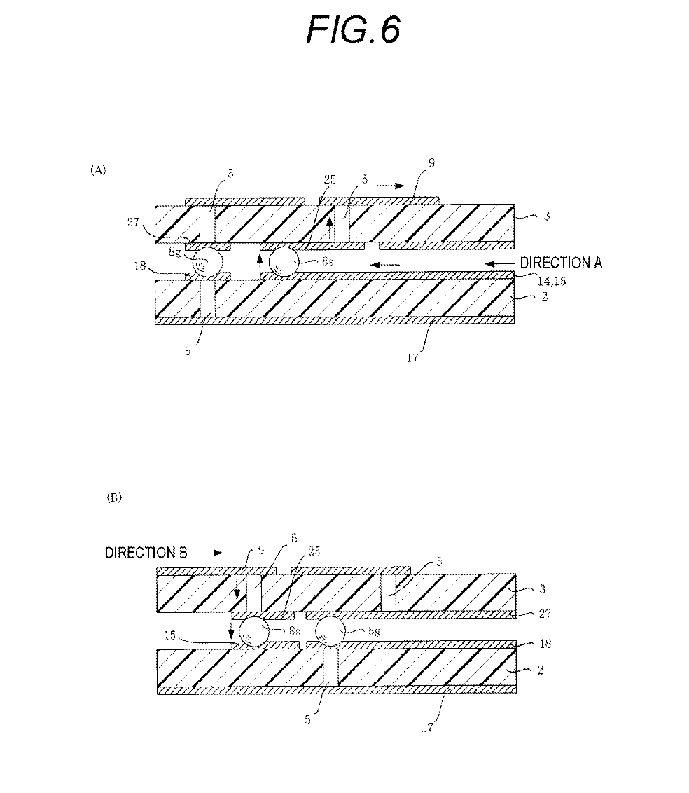

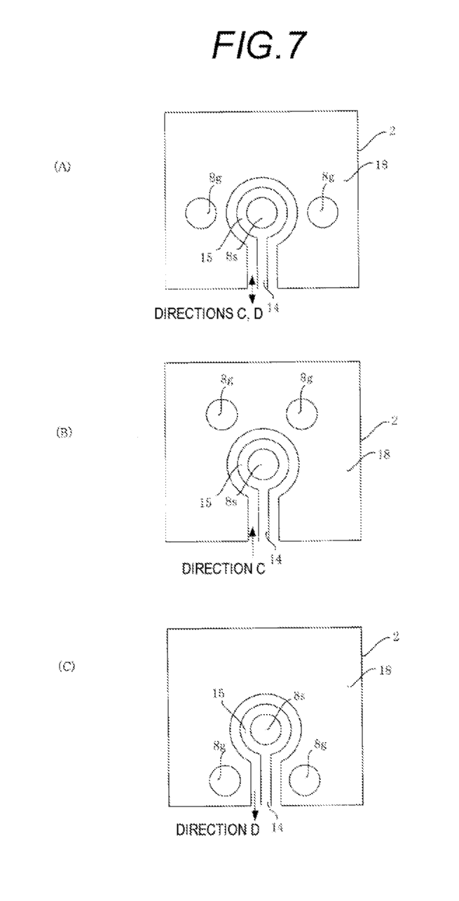

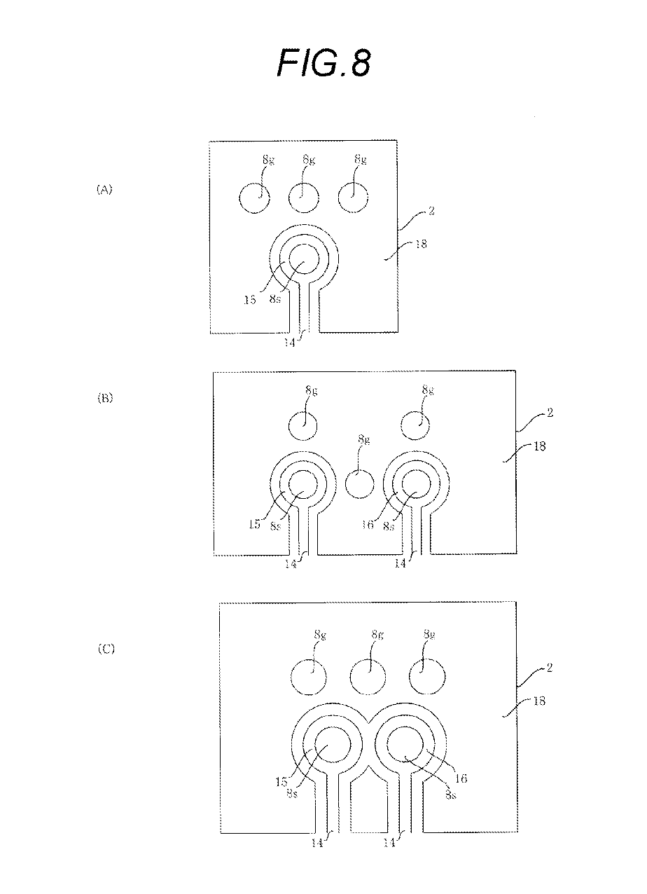

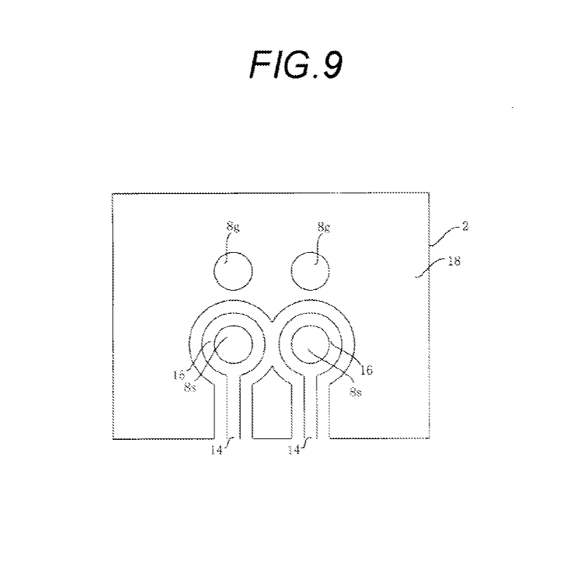

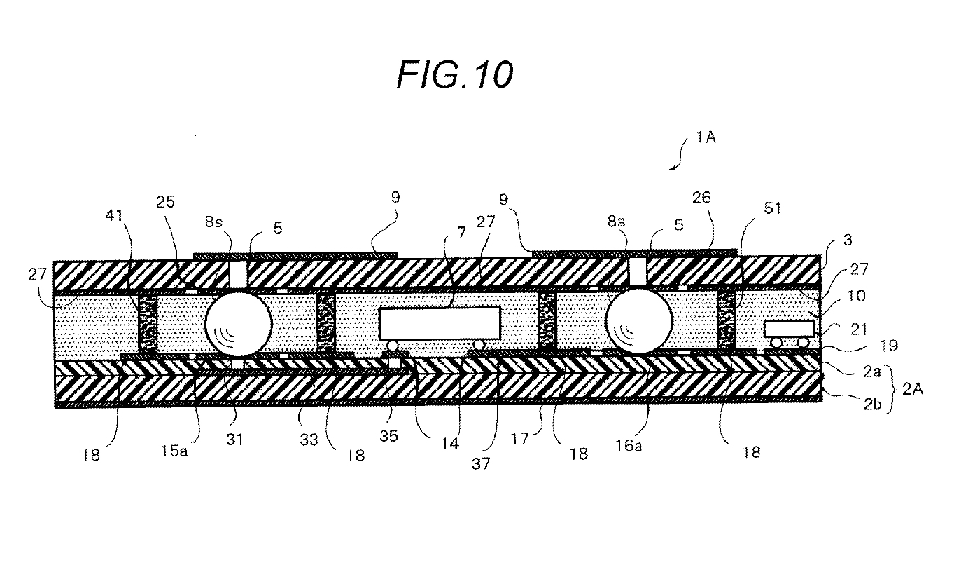

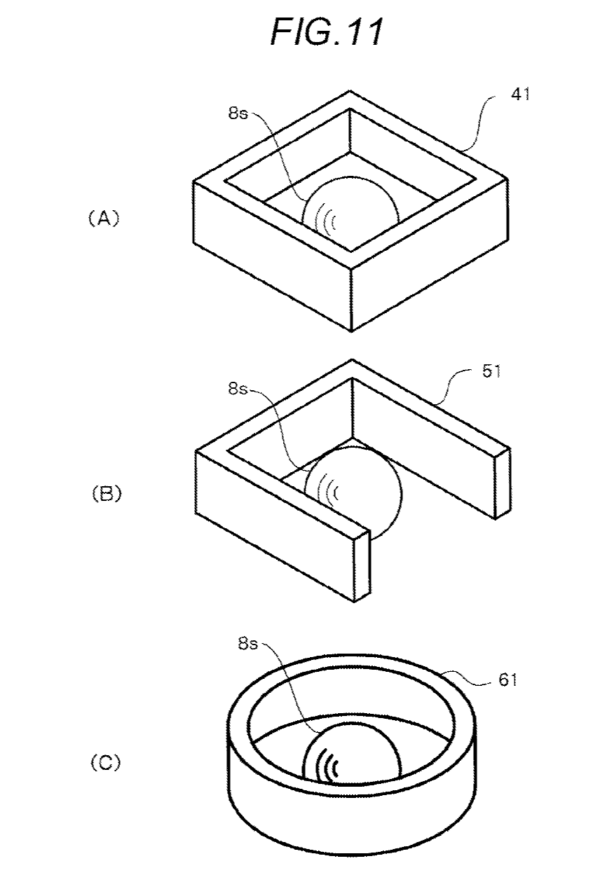

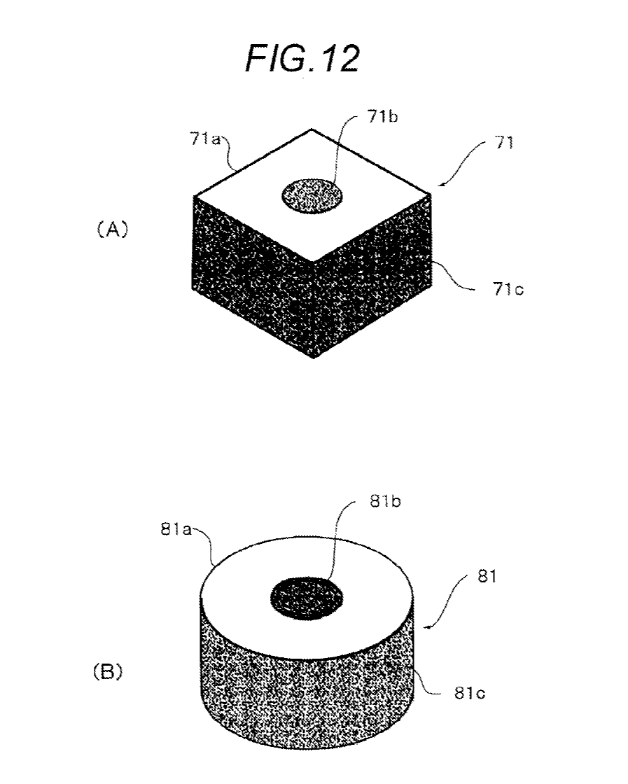

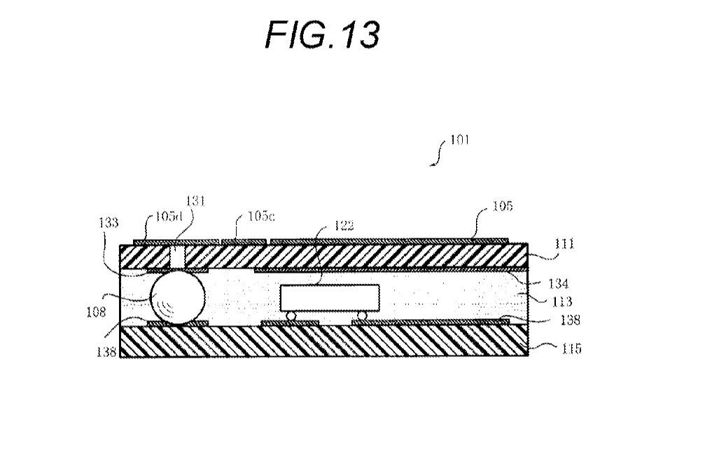

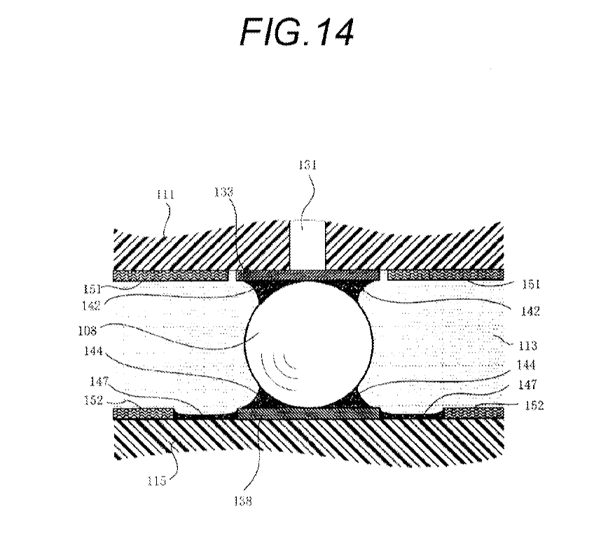

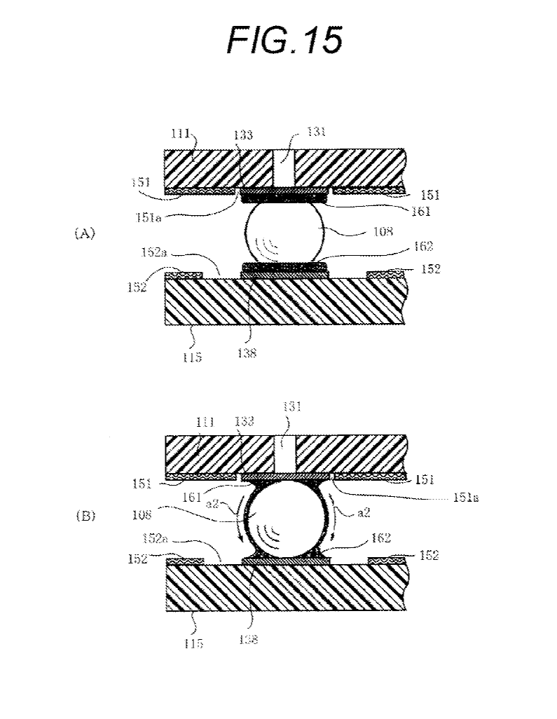

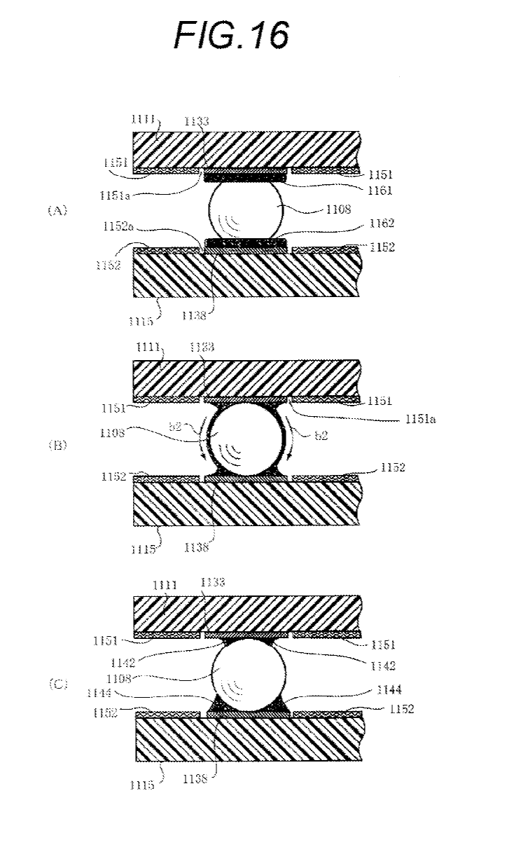

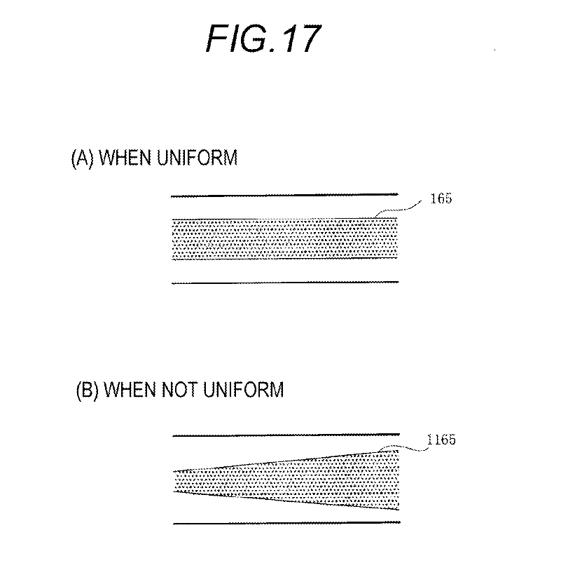

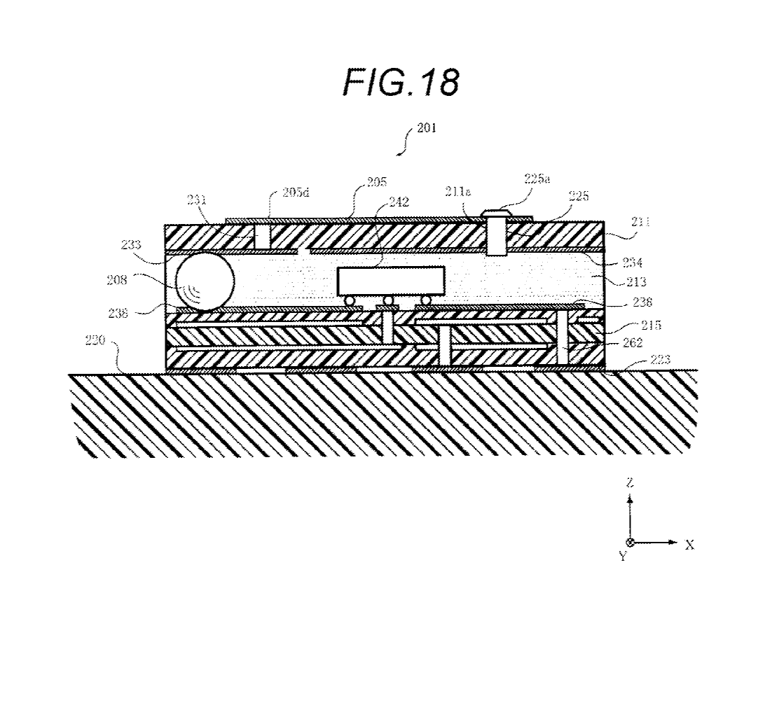

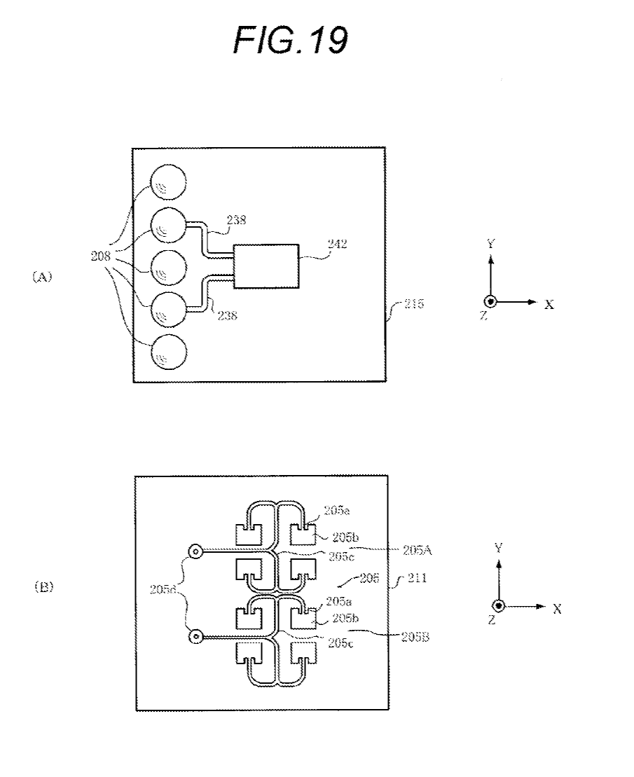

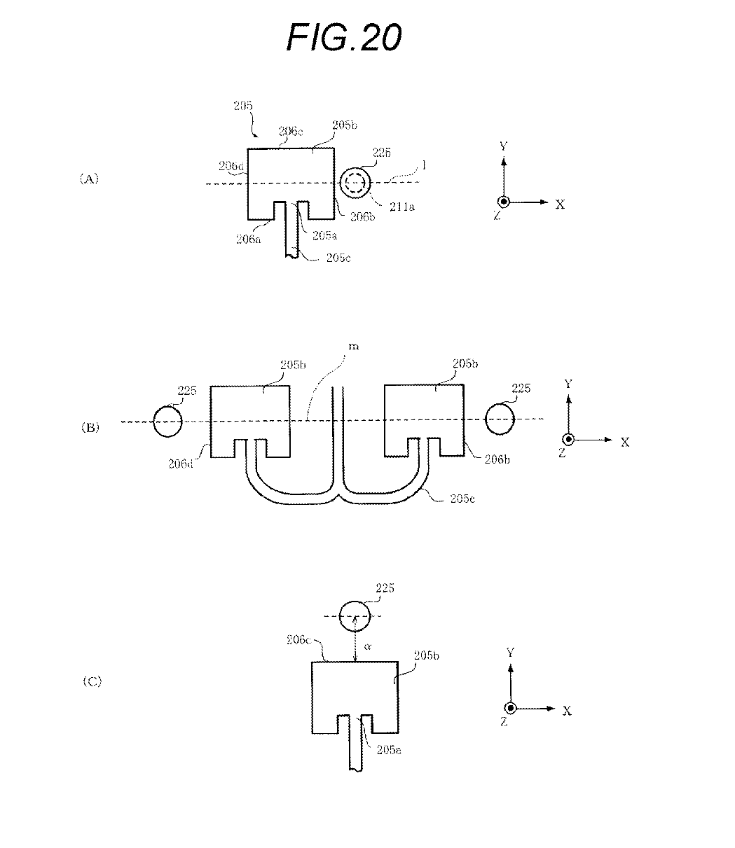

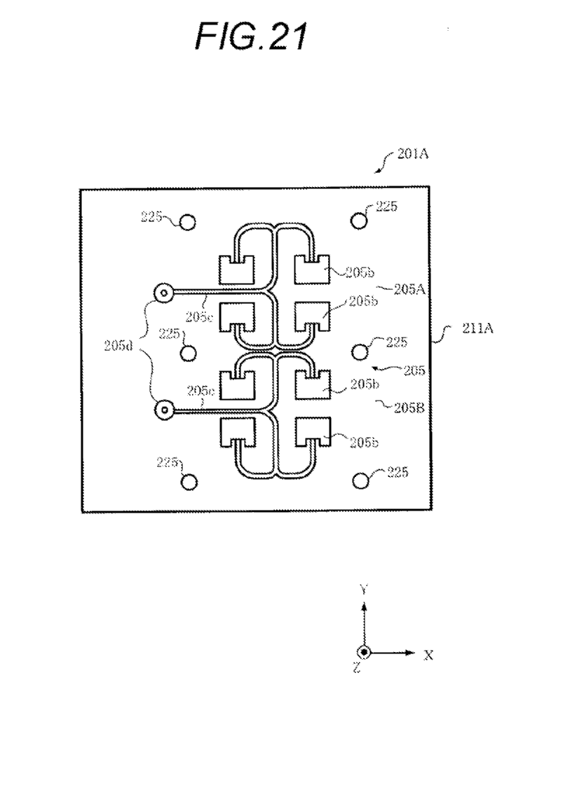

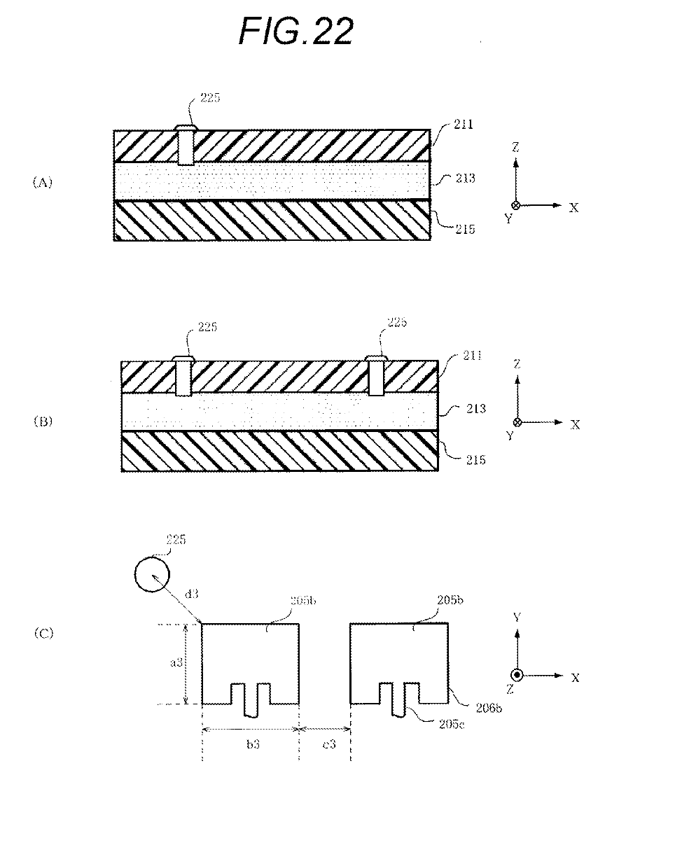

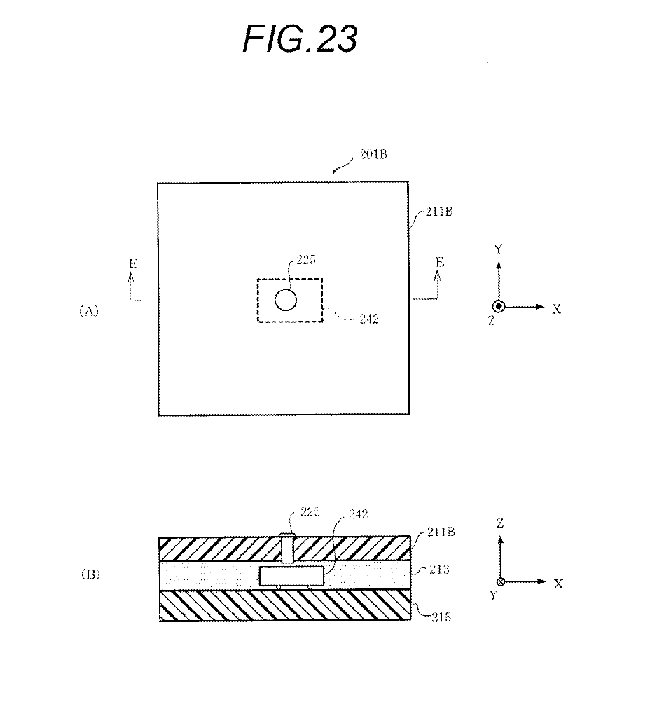

FIG. 4 is a graph showing a simulation result of change in transmission loss corresponding to a frequency for each number of ground copper core solder balls. The transmission loss changes depending on the number of ground copper core solder balls 8g surrounding the respective copper core solder balls 8s for signal transmission. A bold line a indicates that the number of ground copper core solder balls 8g is four and the transmission loss is substantially reduced uniformly in a range of 57.5 GHz to 62.5 GHz centering on 60 GHz.

A broken line b indicates that the number of copper core solder balls 8g is three and the transmission loss is reduced overall compared to the bold line a and is further reduced on the 62.5 GHz side. A solid line c indicates that the number of ground copper core solder balls 8g is two and the transmission loss is reduced greatly compared to other cases and is reduced more greatly on the 57.5 GHz side. In the wireless module 1 of this embodiment, since the number of ground copper core solder balls 8g is five, it is possible to further suppress the transmission loss.

In this way, in this example, as the number of ground copper core solder balls 8g increases, the transmission loss (radiation loss) decreases. In particular, when the number of copper core solder balls 8g is equal to or greater than three, it is possible to significantly suppress the transmission loss. For example, if it is possible to suppress the transmission loss by 3 dB, it is possible to reduce the amount of power half.

In the foregoing example, although a case where the transmission loss is reduced according to the number of copper core solder balls 8g, next, change in transmission loss depending on the arrangement of the copper core solder balls 8g will be described.

FIGS. 5(A) to 5(C) are plan views of the lower board 2 when the wireless module 1 is viewed in perspective view from the top to the bottom. FIGS. 5(A) to 5(C) show an example of the arrangement relationship of one signal copper core solder ball 1 and three ground copper core solder balls 3. FIGS. 6(A) and 6(B) are an example of cross-sectional views of the wireless module 1 shown in FIGS. 5(A) to 5(C) taken along the line A-A′. FIGS. 6(A) and 6(B) are in a simplified form, and for example, the filling material 10 is omitted.

FIG. 6(A) illustrates that a signal is transmitted from the opposing surfaces of the upper board 3 and the lower board 2, and is transmitted in the direction of an arrow A. That is, in FIG. 6(A), a signal is transmitted in an order of the wiring pattern 14, the wiring pad 15, the signal copper core solder ball 8s, the wiring pad 25, the through-via 5, and the antenna 9. The flow of a signal of the arrow A is, for example, the flow when a signal is transmitted by the wireless module 1.

FIG. 6(B) illustrates that a signal is transmitted from the front surface of the upper board 3, and is transmitted in the direction of an arrow B. That is, in FIG. 6(B), a signal is transmitted in an order of the antenna 9, the through-via 5, the wiring pad 25, the signal copper core solder ball 8s, and the wiring pad 15. Thereafter, for example, a signal is input to an electronic component through a wiring pattern (not shown). The flow of a signal of the arrow B is, for example, the flow when a signal is received by the wireless module 1.

The antenna 9, the wiring patterns 14 and the wiring pads 15, 16, and 25 are examples of signal wiring pads or signal wirings.

In FIG. 5(A), the ground copper core solder balls 8g are arranged so as to surround the signal copper core solder balls 8s. In the arrangement of the ground copper core solder balls 8g, from the restrictions of wiring in a portion in which the copper core solder balls 8g are mounted, and the copper core solder balls 8g may not be arranged sufficiently densely. The restrictions of wiring include, for example, an interval of wiring space, an aperture size of a solder resist, or mounting failure. The mounting failure includes, for example, connection of the copper core solder balls 8g to other solder balls during solder reflow, or deviation of the copper core solder balls 8g from the mounting portion.

For example, as described above, when the diameter of the copper core solder balls 8s and 8g is 200 um, and the diameter of the wiring pads 15 is 300 um, if the arrangement is made with a wiring restriction of a line-space interval 50 um, the ends on the sides facing each copper core solder ball are separated from each other at 150 um. The line-space interval indicates an area with no metal between wirings, and is the rule for board design.

For example, when one signal copper core solder ball 8s is surrounded by three ground copper core solder balls 8g, as shown in FIG. 5(A), the three copper core solder balls 8g may be arranged evenly, for example, on the upper side, the left side, and the right side with respect to the copper core solder ball 8s.

As shown in FIG. 5(B), the arrangement may be made such that the interval between the three ground copper core solder balls 8g satisfies the above-described restriction and becomes minimal. When the interval between the copper core solder balls 8g is minimal, for example, this indicates that the distance (for example, distance L1) between the centers of the copper core solder balls 8g is two times the diameter of each copper core solder ball 8g. The distance between the centers of the signal copper core solder ball 8s and any ground copper core solder ball 8g is two times the diameter of the copper core solder balls 8s and 8g.

As shown in FIG. 5(C), the ground copper core solder balls 8g and the wiring pattern 14 connected to the wiring pad 15 of the signal copper core solder ball 8s may be arranged such that the above-described restriction is satisfied and becomes minimal. When the interval from the wiring is minimal, for example, this indicates that the interval (for example, the interval L2) between the end portion of each of the two left and right copper core solder balls 8g on the wiring pattern 14 side and the end portion of the wiring pattern 14 on the copper core solder ball 8g side is minimal.

The positional relationship between the copper core solder balls 8s and 8g may be determined by the balance with other wiring layers and component arrangement. For example, when a signal is transmitted from the wiring pattern 14 to the wiring pad 15 shown in FIG. 6(A), a current which is excited in a ground electrode is determined according to a current which flows in the wiring.

For example, when a signal passes through the copper core solder ball 8s, a current which is excited in the ground electrode increases on the left side in FIGS. 6(A) and 6(B) and on the upper side in FIGS. 5(A) to 5(C). In this case, with the arrangement of the copper core solder balls 8g shown in FIG. 5(B), it is possible to allow the passage of the current excited in the ground electrode at a shorter distance, and to decrease wiring impedance, thereby reducing radiation due to loss or reflection.

FIGS. 7(A) to 7(C) are plan views of the lower board 2 when the wireless module 1 is viewed in perspective view from the top to the bottom. FIGS. 7(A) to 7(C) show an example of the arrangement relationship between one signal copper core solder ball and two ground copper core solder balls.

FIG. 7(A) shows a case where there is no copper core solder ball 8g arranged on the upper side of the copper core solder ball 8s in FIG. 5(A). FIG. 7(B) shows a case where there is no copper core solder ball 8g arranged on the upper side of the copper core solder ball 8s in FIG. 5(B). FIG. 7(C) shows a case where there is no copper core solder ball 8g arranged on the upper side of the copper core solder ball 8s in FIG. 5(C).

In FIGS. 7(A) to 7(C), the features of an electrical characteristic in the arrangement of the respective copper core solder balls 8g are the same as in the cases of FIGS. 5(A) to 5(C). In the arrangement relationship of FIG. 7(B), it is preferable that a signal is transmitted in the direction of an arrow C. In the arrangement relationship of FIG. 7(C), it is preferable that a signal is transmitted in the direction of an arrow D. The arrangement relationship of FIG. 7(A) is suitable for a case where a signal is transmitted in both directions of the arrow C and the arrow D. A characteristic c: two shown in FIG. 4 is a simulation result in the case of the arrangement of FIG. 7(A).

Next, the features in the arrangement of the copper core solder balls 8g of FIGS. 8(A) to 8(C) and 9 will be described.

As already described, the ground copper core solder balls 8g arranged around the signal copper core solder ball 8s are arranged at the same positions as in FIGS. 5(A) to 5(C) and 7(A) to 7(C), and may be arranged at other positions according to the arrangement of other wirings or components.

FIGS. 8(A) to 8(C) are plan views of the lower board 2 when the wireless module 1 is viewed in perspective view from the top to the bottom. FIG. 8(A) shows an example of the arrangement relationship between one signal copper core solder ball and three ground copper core solder balls. FIGS. 8(B) and 8(C) show an example of the arrangement relationship between two signal copper core solder balls and three ground copper core solder balls.

In FIG. 8(A), ground copper core solder balls are substantially arranged in a row above the copper core solder ball 8s. In this case, a characteristic close to that in the case of FIG. 5(B) is obtained.

The arrangement relationship shown in FIG. 8(B) is used when separating a signal to be transmitted in two signal copper core solder balls 8s. In FIG. 8(B), among the three ground copper core solder balls, the central ground copper core solder ball 8g is shared by the respective signal copper core solder balls 8s. The central ground copper core solder ball 8g is arranged between two signal copper core solder balls 8s.

With the arrangement of FIG. 8(B), similarly to FIG. 2(A), radiation of electric waves is reduced, mutual coupling between the two signal copper core solder balls 8s is weakened, and mutual interference decreases. When comparing with the case of FIG. 2(A), since the arrangement area decreases, the wireless module 1 can also be reduced in size.

In FIG. 8(C), among the three ground copper core solder balls 8g, the central copper core solder ball 8g is shared by the left and right signal copper core solder balls 8s. The three copper core solder balls 8g are substantially arranged in a row above the two signal copper core solder balls 8s. With the arrangement of FIG. 8(C), since the arrangement area further decreases compared to that in the case of FIG. 8(B), further reduction in size can be achieved.

As shown in FIG. 9, two ground copper core solder balls 8g may be shared by two signal copper core solder balls 8s. With the arrangement of FIG. 9, a characteristic close to that in FIG. 7(B) is obtained.

With the above, in the wireless module 1 of this embodiment, the copper core solder ball 8s for signal transmission is surrounded by the ground copper core solder balls 8g, thereby reducing a radiation loss of signal waves radiated from the transmission line. Accordingly, the wireless module 1 can suppress an increase in power consumption in the wireless module 1.

### Second Embodiment

In a second embodiment, when surrounding the copper core solder ball for signal transmission, a tubular or U-shaped conductive member is used without using the ground copper core solder balls.

A wireless module of the second embodiment substantially has the same configuration as in the first embodiment. The same components as those in the first embodiment are represented by the same reference numerals, and description thereof will not be repeated.

FIG. 10 is a cross-sectional view showing the internal structure of a wireless module 1A of the second embodiment. In the wireless module 1A, a lower board 2A has a multilayer structure having at least two layers in which a first layer board 2a and a second layer board 2b are bonded together. Copper core solder balls 8s are mounted on wiring pads 15a and 16a formed on the upper surface of the first layer board 2a.

Wiring patterns 33 which are electrically connected to the wiring pads 15a through through-vias 31 and 35 are formed on the upper surface of the second layer board 2b.

FIGS. 11(A) to 11(C) are perspective views showing various conductive members 41, 51, and 61. In the second embodiment, instead of the ground copper core solder balls in the first embodiment, a conductive member 41 (frame member) having a tubular quadrangular frame shown in FIG. 11(A) is formed so as to surround the copper core solder ball 8s for signal transmission and is soldered to the ground pattern 18. Accordingly, since the periphery of the copper core solder ball 8s for signal transmission is entirely connected to the ground, it is possible to reduce radiation from the copper core solder ball 8s for signal transmission.

In contrast, since there is the conductive member 41 having the tubular quadrangular frame, if the wiring pattern 14 and the wiring pad 15a are directly connected together, this causes contact with conductive member 41. For this reason, a signal line of the semiconductor device 7 is electrically connected to the wiring pad 15a through the wiring pattern 14, a through-via 35, a wiring pattern 33, and a through-via 31.

On the upper surface of the first layer board 2a, a wiring pattern 37 which electrically connects the wiring patterns 14 having the semiconductor device 7 mounted thereon and the wiring pad 16a, to which the copper core solder ball 8s for signal transmission is soldered, is formed.

In FIG. 11(B), the U-shaped conductive member 51 is formed so as to surround the copper core solder ball 8s for signal transmission soldered to the wiring pad 16a, and is soldered to the ground pattern 18.

In this case, since a part of the periphery of the conductive member 51 (on the semiconductor device 7 side) is opened, the wiring pad 16a and the wiring pattern 14 can directly contact each other.

In this way, in the conductive member 41 having the tubular quadrangular frame, since the wiring pad 15a is located inside the conductive member 41, in order to form a signal line leading to the wiring pad 15a, a multilayer board is required. In the U-shaped conductive member 51, it is possible to lead a signal line from the opened surface. Accordingly, in the wireless module 1A of this embodiment, it is possible to simplify the structure of the lower board, and with the use of the U-shaped conductive member, it is possible to a single layer board for the lower board.

In this way, in the second embodiment, in the wireless module LA, the copper core solder ball 8s for signal transmission as a transmission line is surrounded using the conductive member 41 or 51, thereby grounding the periphery of the transmission path. Accordingly, in the wireless module 1A, it is possible to suppress radiation of a signal from the copper core solder ball 8s for signal transmission as the transmission path, and to reduce a transmission loss (radiation loss).

The conductive member is not limited to a rectangular frame and may be a cylindrical conductive member 61 shown in FIG. 11(C). Similarly to FIGS. 11(A) and 11(B), the conductive member 61 is soldered to the ground pattern 18 such that the copper core solder ball 8s for signal transmission is located inside the cylinder.

In the case of the conductive members of FIGS. 11(A), 11(B), and 11(C), a hole is provided in the conductive member so as to allow a filler to be easily injected.

### Third Embodiment

In a third embodiment, a coaxial member with a signal line and a ground line coaxially integrated is used without using a copper core solder ball for signal transmission. A wireless module of the third embodiment has the same configuration as in the first or second embodiment, excluding a copper core solder ball for signal transmission.

FIGS. 12(A) and 12(B) are perspective views showing the structures of coaxial members 71 and 81 in the third embodiment. In FIG. 12(A), the coaxial member 71 has a body portion 71a which is formed in a cube using an insulating material of ceramic or resin. A signal line 71b which provides electrical conduction between wiring pads 15a and 25 is inserted at the center of the body portion 71a.

On the outer surface of the body portion 71a, a conductive material 71c (for example, silver) is formed by baking or vapor deposition, and becomes a ground line which provides electrical conduction between the ground patterns 18 and 27. When the conductive material 71c is formed on the entire outer surface of the body portion 71a, similarly to the conductive member 41 shown in FIG. 11(A), it is necessary to use a multilayer board for the lower board 2A and to ensure a transmission line. When a part of the outer surface of the body portion 71a is opened, since it is possible to lead a signal line from the opened surface, a single layer board may be used for the lower board 2A.

In the third embodiment, a coaxial member 81 shown in FIG. 12(B) may be formed instead of the coaxial member 71 shown in FIG. 12(A). The coaxial member 81 has a cylindrical body portion 81a using an insulating material of ceramic or resin. On the inner and outer surfaces of the cylindrical body portion 81a, conductive materials (for example, silver) 81b and 81c are formed by baking or vapor deposition.

The inner conductive material 81b becomes a signal line. The outer conductive material 81c becomes a ground line which provides electrical conduction between the ground patterns 18 and 27.

In the third embodiment, with the use of the coaxial member, it is possible to surround the transmission line by the ground simply and uniformly, and to reduce a radiation loss of a signal radiated from the transmission line of the coaxial member.

Although various embodiments have been described referring to the drawings, it should be noted that the present disclosure is not limited to such examples. It is obvious to those skilled in the art that various alteration examples or modification examples may be made within the scope described in the appended claims, and it is understood that these examples still fall within the technical scope of the present disclosure.

For example, in the foregoing embodiments, although a case where the five ground copper core solder balls 8g are arranged in the periphery of the copper core solder ball 8s for signal transmission, for example, an arbitrary number of (three or more) ground copper core solder balls may be arranged at positions, at which the periphery are divided into eight equal parts, that is, at arbitrary positions.

In the foregoing embodiments, although the structure of the upper board having the antenna formed thereon is a single layer structure, similarly to the lower board, the upper board may have a multilayer structure.

In the foregoing embodiments, although the ground copper core solder balls 8g are arranged in the periphery of the copper core solder ball 8s for signal transmission which is used for signal transmission with the antenna, the ground copper core solder balls 8g may be arranged in the periphery of a copper core solder ball for signal transmission which is used for signal transmission with a different electronic component (not shown) mounted on the upper board 3.

(Background to Another Form of the Present Disclosure)

In the wireless module of the related art, when connecting the second board as the upper board and the first board as the lower board using the copper core balls by soldering, the solder molten on the upper board flows toward the lower board by gravity. For this reason, after the solder is solidified, the solder fillet (a portion of solder protruded) formed on the lower board side becomes larger than that on the upper board side.

As a result, impedance of the signal transmission line between the upper and lower boards changes discontinuously. In particular, in wireless communication using a high-frequency range of millimeter waves, a transmission loss of a signal between the upper and lower boards increases.

In the following embodiment, in wireless communication in a high-frequency range including a millimeter-wave band, a wireless module which suppresses impedance discontinuity of the signal transmission line will be described.

### Fourth Embodiment

A wireless module of this embodiment is used as a part of a wireless communication circuit which has an antenna mounted on a board and performs wireless communication using a high frequency in a millimeter-wave band.

FIG. 13 is a cross-sectional view showing the internal structure of a wireless module 101 of this embodiment. The wireless module 101 is mounted on a set board (not shown) on which various electronic components are mounted, and includes an upper board 111 and a lower board 115 arranged to face each other. In the wireless module 101, a plurality of copper core balls 108 are provided between the upper board 111 and the lower board 115, a filling material 113 (for example, resin) is filled in the space between the upper board 111 and the lower board 115, and the upper board 111 and the lower board 115 are sealed.

The upper board 111 is formed using, for example, an insulating material of a dielectric having a dielectric constant of about 3 to 4, and has a single layer structure. An antenna 105 is formed on the upper surface (the upper side of FIG. 13) of the upper board 111 (first board). On the lower surface opposite to the upper surface of the upper board 111, a wiring pad 133 (first wiring portion) for electrically connecting the copper core ball 108 and a ground pattern 134 is formed. The copper core ball 108 is soldered to the wiring pad 133.

On the upper surface of the upper board 111, a signal pad 105d electrically connected to the wiring pad 133 through the through-via 131 is formed. On the upper surface of the upper board 111, the antenna 105 is constituted in a pad shape using copper foil, and is connected to the signal pad 105d through a feed line 105c.

In this way, the signal pad 105d connected to the antenna 105 is connected to the wiring pad 133 on the lower surface through a through-via 131 formed in the upper board 111, and is also electrically connected to a wiring pad 138 (second wiring portion) formed on the lower board 115 through the copper core ball 108. The copper core ball 108 is soldered to the wiring pad 138.

The lower board 115 is formed using, for example, an insulating material of a dielectric having a dielectric constant of about 3 to 4 and has a single layer structure. An electronic component, for example, a semiconductor device (for example, IC) 122, a chip capacitor (not shown), or a crystal oscillator (not shown) connected to the wiring pad 138 is mounted on the lower board 115 (second board).

FIG. 14 is an enlarged view of a soldering location of the copper core ball 108 connected between the upper board 111 and the lower board 115. The upper surface (one surface) of the copper core ball 108 is soldered to the wiring pad 133 formed on the upper board 111. A solder fillet 142 (first solder connection shape) is formed at the soldering position of the wiring pad 133 and the copper core ball 108 so as to fill a gap.

A solder resist 151 is applied or printed in the periphery of the wiring pad 133 so as to prevent an excess solder from being stuck to other portions during soldering. The solder resist primarily contains resin, an additive, a photoinitiator, an organic solvent, and a filler, and is known ink as an insulating protective film so as not to prevent electrical conduction of a portion other than soldering. In FIG. 13, the solder resist is omitted.

The lower surface (the other surface) of the copper core ball 108 is soldered to the wiring pad 138 formed on the lower board 115. A solder fillet 144 (second solder connection shape) is formed at the soldering position of the wiring pad 138 and the copper core ball 108 so as to fill a gap. A solder resist 152 is applied or printed in the periphery of the wiring pad 138 so as to prevent an excess solder from being stuck to other portions during soldering. During soldering, an excess solder 147 which is molten, overflows, and is solidified is attached to the surface of the lower board 115 between the wiring pad 138 and the solder resist 152.

FIGS. 15(A) and 15(B) are diagrams showing behavior of a solder during soldering. In this embodiment, the copper core ball 108 provided between the upper board 111 and the lower board 115 is soldered using a known reflow method. That is, soldering is performed in a state where the upper board 111 and the lower board 115 are arranged in a vertical direction with the upper board 111 on the upper side.

In a reflow method shown in FIG. 15(A), solder creams 161 and 162 are applied or printed in the portions of the wiring pads 133 and 138 to which the copper core ball 108 on the lower surface of the upper board 111 and the upper surface of the lower board 115 are connected. On the lower surface of the upper board 111 and the upper surface of the lower board 115, solder resists 151 and 152 are not applied or printed such that portions surrounding the wiring pads 133 and 138 become openings 151a and 152a.

The solder resists 151 and 152 are insulating protective films which prevent an excess solder from being stuck to other portions during soldering. In this embodiment, the opening 152a (second opening) of the lower solder resist 152 is formed to be wider than the opening 151a (first opening) of the upper solder resist 151.

That is, in the openings 151a and 152a, no solder resist is applied or printed, thereby adjusting the amount of the solder fillet 144 on the wiring pad 138.

In FIG. 15(B), if heat is applied in soldering, a solder cream 161 applied to the upper board 111 is molten, and a part of the molten solder flows along the surface of the copper core ball 108 as indicated by an arrow a2 excluding the connection portion of the wiring pad 133 and the copper core ball 108. In the connection portion on the upper board 111 side, a solder remains by the amount compatible with surface tension of the wiring pad 133 and the copper core ball 108, and solder fillet 142 is formed (see FIG. 14).

Similarly to the upper board 111, if heat is applied in soldering, a solder cream 162 applied to the lower board 115 is molten, and a part of the solder flowing from the upper board 111 side becomes the connection portion of the wiring pad 138 and the copper core ball 108. In the connection portion on the lower board 115 side, a solder remains by the amount compatible with surface tension, and a solder fillet 144 is formed (see FIG. 14). The remaining solder flows into the opening 152a in which there is no solder resist 152, is widely spread and solidified on the upper surface of the lower board 115 by surface tension of the wiring pad 138 and the copper core ball 108, and remains inside the opening 152a.

As a result, the solder fillet 142 on the upper board side and the solder fillet 144 on the lower board side are of symmetrical, substantially equal size (see FIG. 14).

The opening 152a of the solder resist 152 has a width such that the amount of the solder which is applied to the wiring pad 133, exceeds the size of the solder fillet 142 compatible with surface tension, and flows into the wiring pad 138 along the surface of the copper core ball 108 is receivable.

Accordingly, it is possible to adjust the width of the opening 152a according to the amount of the solder cream to be applied. There is allowance for the width of the opening 152a, whereby, even if the amount of the solder creams 161 and 162 is somewhat deviated, it is possible to allow the deviated amount to be absorbed in the opening 152a, and to align the solder fillet 142 on the upper board side and the solder fillet 144 on the lower board side to be of symmetrical, substantially equal size.

FIGS. 16(A), 16(B), and 16(C) are diagrams showing behavior of a solder in soldering of the related art. In FIG. 16(A), an opening 1152a of a solder resist 1152 applied to a lower board 1115 and an opening 1151a of a solder resist 1151 applied to a upper board 1111 are formed to be slightly larger than the thickness of wiring pads 1133 and 1138, and are of substantially equal size.

In FIG. 16(B), if solder creams 1161 and 1162 are molten, in the connection portion of the wiring pad 1133 and a copper core ball 1108 of the molten solder, a solder remains by the amount compatible with surface tension. As indicated by an arrow b2, the remaining solder flows toward the lower board 1115 and remains between the copper core ball 1108 and the wiring pad 1138.

As a result, in FIG. 16(C), a solder fillet 1144 formed in the connection portion on the lower board 1115 side becomes larger than a solder fillet 1142 formed in the connection portion on the upper board 1111 side.

FIGS. 17(A) and 17(B) are diagrams showing an image of a transmission line along a copper core ball between an upper board and a lower board. FIG. 17(A) is a diagram showing when uniform. FIG. 17(B) is a diagram showing when not uniform. In this embodiment, solder fillets 142 and 144 (see FIG. 14) having a symmetrical, substantially equal shape are formed. That is, as shown in FIG. 17(A), a transmission line 165 between an upper board 111 and a lower board 115 has a uniform shape. Accordingly, the transmission line 165 can suppress discontinuous change in impedance.

In FIG. 16(C), the solder fillet 1144 on the lower board side is larger than the solder fillet 1142 on the upper board side and is asymmetrical. In this case, as shown in FIG. 17(B), a transmission line 1165 between the upper board 1111 and the lower board 1115 has a non-uniform shape. Accordingly, in the transmission line 1165, impedance on the lower board side decreases, and discontinuous change occurs on the upper board side and the lower board side.

A wireless module of this embodiment, it is possible to make the shape of the solder fillet at a location, at which the copper core ball is connected, substantially equal, and to suppress impedance discontinuity of the signal transmission line. Accordingly, in the wireless module of this embodiment, when transmitting a millimeter-wave signal between the upper and lower boards, it is possible to decrease a transmission loss of a signal.

According to this embodiment, in wireless communication in a high-frequency range including a millimeter-wave band, it is possible to suppress impedance discontinuity of the signal transmission line.

Although various embodiments have been described referring to the drawings, it should be noted that the present disclosure is not limited to such examples. It is obvious to those skilled in the art that various alteration examples or modification examples may be made within the scope described in the appended claims, and it is understood that these examples still fall within the technical scope of the present disclosure.

For example, in the foregoing embodiments, although a conductive sphere (copper core ball) is used as a conductive member, a different shape, for example, a block shape or a columnar shape may be used.

In the foregoing embodiments, although soldering is performed using the reflow method, soldering is not limited to the reflow method.

In the foregoing embodiments, the boards may be reversed, an upper board having an antenna formed thereon may be on the lower side in the vertical direction, a lower board having an electronic component, such as a semiconductor device, a chip capacitor, or a crystal oscillator, mounted thereon may be on the upper side, and soldering may be performed.

(Background to Yet Another Form of the Present Disclosure)

In the semiconductor apparatus of Patent Literature 1, the bonding of the silicon board (upper board) having the antenna formed thereon and the wiring board (lower board) having the electronic component (for example, the semiconductor device (IC)) mounted thereon is maintained by sealing the filling material. However, the upper board, the filling material, and the lower board may contain different materials. In this case, from the difference in the coefficient of thermal expansion between the materials, if heat is applied due to heat generation in the semiconductor device (IC) mounted on the lower board, the upper board is likely to be separated from the filling material.

In order to prevent separation, a hole is formed in the upper board, a rib protrudes from the hole and is buried in the filling material, and the upper board is pressed in the filling material using the rib, thereby restricting movement of the upper board.

As an example, a case where communication is performed using the wireless module of the related art, in which the size of the rib is 0.4 mm, will be described. In communication in a 5 GHz band which is a centimetric-wave band, since the wavelength λ=60 mm and the ratio of the wavelength and the size of the rib is 1/150, the size of the rib is negligible. In contrast, in communication in a 60 GHz band which is a millimeter-wave band, the wavelength λ=5 mm and the ratio of the wavelength and the size of the rib is 1/12.5, it is necessary to take an influence on the performance of the antenna into consideration.

In this way, in the wireless module which performs high-frequency communication (for example, millimeter-wave communication), if the rib is provided, since the size of the rib is relatively large with respect to the wavelength, there is not a little influence on the performance of the antenna.

In the following embodiment, a wireless module which can prevent separation of a board of a wireless module and can perform satisfactory high-frequency communication will be described.

### Fifth Embodiment

FIG. 18 is a cross-sectional view showing a structure example of a wireless module 201 according to a fifth embodiment of the present disclosure. The wireless module 201 is mounted on a set board 220 on which an electronic circuit is formed. The wireless module 201 is formed by providing a plurality of copper core solder balls (Cu core balls) 208 between an upper board 211 and a lower board 215, and filling a filling material 213 (for example, a material including resin) between the upper board 211 and the lower board 215 to seal the space between the boards. The wireless module 201 has a structure in which the upper board 211 and the lower board 215 are bonded together.

FIGS. 19(A) and 19(B) are plan views showing a configuration example of the lower board 215 and the upper board 211. FIG. 19(A) shows the lower board 215 when the wireless module 201 is viewed from the top in perspective view. FIG. 19(B) shows the upper board 211 when the wireless module 201 is viewed from the top in perspective view.

In FIG. 18, the upper board 211 is formed using, for example, an insulating material of a dielectric having a dielectric constant of about 3 to 4, and has a single layer structure. An antenna element 205 is formed on the front surface of the upper board 211 (an example of a first board). On the rear surface of the upper board 211, a wiring pad 233 for electrically connecting the copper core solder ball 208 and a ground pattern 234 are formed. The copper core solder ball 208 is soldered to the wiring pad 233.

A signal pad 205d of the antenna element 205 is electrically connected to a wiring pattern 238 formed on the lower board 215 through a through-via 231 formed in the upper board 211, the wiring pad 233 on the rear surface, and the copper core solder ball 208. The copper core solder ball 208 is also soldered to the wiring pattern 238.

In FIG. 19(B), on the upper surface (front surface) of the upper board 211, the signal pad 205d and pad-like copper foil antennas 205A and 205B connected to the signal pad 205d through a feed line 205c are formed.

In FIG. 18, the lower board 215 is formed using, for example, an insulating material of a dielectric having a dielectric constant of about 3 to 4, and has a multilayer structure. On the lower board 215 (an example of a second board), an electronic component, for example, a semiconductor device (IC) 242, a chip capacitor (not shown), or crystal oscillator (not shown) connected to the wiring pattern 238 is mounted. The wiring pattern 238 formed on the lower board 215 is electrically connected to a wiring pattern 223 formed on the set board 220 through a through-via 262.

The antenna element 205 primarily includes an antenna 205A for reception and the antenna 205B for transmission. The antennas 205A and 205B have four rectangular patches (antenna patches) 205b with sides having four feeding points 205a, at which an electric field concentrates, formed thereon. Each feeding point 205a is connected to the signal pad 205d through the feed line 205c.

As the materials for the upper board 211, the filling material 213, and the lower board 215, for example, an epoxy-based or polypropylene-based resin material is used. As the material for a component (for example, the semiconductor device 242) embedded in the wireless module 201, a silicon material is used. For this reason, as described above, when the embedded component (for example, the semiconductor device 242) generates heat and increases in temperature, from the difference in the coefficient of thermal expansion between the materials, the upper board 211 or the lower board 215 is likely to be separated from the filling material 213.

In the wireless module 201, a rib 225 (an example of a locking member) which passes through a hole 211a formed in the upper board 211 and protrudes into the filling material 213 is provided. The rib 225 is a columnar resin member having a head portion 225a. A part of the rib 225 protruding from the hole 211a of the upper board 211 is buried in the filling material 213 or is pressed in the filling material 213, whereby the rib 225 restricts movement of the upper board 211 and suppresses separation of the upper board 211 of the wireless module 201.

However, since the rib 225 is a dielectric, when the arrangement is made without taking the positional relationship between the rib 225 and the antennas 205A and 205B into consideration, since the performance of the antenna may be degraded, in this embodiment, the arrangement of the rib 225 will be studied.

Next, the positional relationship between the antennas 205A and 205B and the rib 225 will be considered.

FIGS. 20(A) to 20(C) are diagrams showing an arrangement example of the rib 225 which is provided in the periphery of a patch 205b of each of the antennas 205A and 205B. A case where four sides 206a, 206b, 206c, and 206d of the patch 205b have a length of about λg/2 and a feeding point 205a is formed on a lower side 206a in FIG. 20(A) is considered. The feed line 205c is connected to the feeding point 205a.

Here, λ is the length of a wavelength in a free space (vacuum), and λg is the length of a wavelength reduced by a dielectric, and these have the relationship of Expression (1). ∈rel is an effective dielectric constant.

λg=λ/(∈rel)^{1/2} (1)

At 60 GHz in a millimeter-wave band, if λ/2 is 2.5 mm and the effective dielectric constant is 4, λg/2 is 1.25 mm.

When the rib 225 is arranged in the periphery of the patch 205b, in FIG. 20(A), it is preferable that the rib 225 is arranged so as to be closest to the middle points of the sides 206b and 206d adjacent to the side 206a, on which the feeding point 205a is formed. That is, the rib 225 is arranged on an X-Y plane on a line 1 which passes through the middle point of the side 206b and is perpendicular to the side 206b. Accordingly, it is possible to minimize the influence of the rib 225 on the performance of the antenna.

While it is obvious that, as the rib 225 is away from the patch 205b, there is less influence of the rib 225 on the high-frequency communication, even if the rib 225 comes into contact with the pattern of the antenna element 205 to some extent, there is little influence of the rib 225. For example, it is allowable that the rib 225 comes into contact with the side 206b of the patch 205b. However, if the hole 211a for a rib overlaps the pattern of the antenna element 205, since the antenna performance is deteriorated, it is necessary to avoid overlapping.

In FIG. 20(B), when two patches 205b are aligned, a pair of ribs 225 are arranged on a line m passing through the middle points of sides 2066b and 206d outside the two patches 205b. The ribs 225 are arranged at these positions, whereby it is possible to minimize the influence of the ribs 225 on the antenna, and to suppress deterioration of the antenna performance.

In FIG. 20(C), when a rib 225 is arranged outside the side 206c of the patch 205b, that is, on the opposite side to the feeding point 205a, the characteristic of the antenna changes depending on the distance a between the rib 225 and the side 206c. For example, when α≧λg/2, there is no change in the directionality of the antenna, and when α<λg/2, the directionality in the front direction (in FIG. 20(C), the vertical direction (Z-axis direction)) of the antenna leans to the rib 225 at about 10 degrees. The closer the position of the rib 225 to the side 206c, the larger the change in the front direction of the antenna.

In this way, with the use of the fact that the arrangement position of the rib 225 changes to change the characteristic of the antenna, mainly; the directionality, it is possible to adjust the directionality of the antenna when the wireless module 201 is mounted on the set board 220 or when the housing of the set board 220 comes close. When adjusting the directionality of the antenna, for example, a plurality of types of upper boards 211 which are different in the position and size of the rib 225 may be prepared, and a board in which the most desirable characteristic is obtained may be selected.

In this way, in the wireless module 201, the rib 225 is arranged in the periphery of the patch 205b excluding the vicinity of the feeding point 205a, at which an electric field concentrates. In the wireless module 201, the antenna element 205 has the rectangular patch 205b having the feeding point 205a. The rib 225 passes through the middle point of the side 206b of the rectangular patch 205b adjacent to the side 206a having the feeding point 205a formed thereon, and is located on the line 1 or m orthogonal to the adjacent side 206b. Accordingly, it is possible to prevent separation of the board of the wireless module 201 for wireless communication in a millimeter-wave band, and to perform satisfactory high-frequency communication.

According to this embodiment, it is possible to prevent separation of a board of a wireless module, and to perform satisfactory high-frequency communication.

### Sixth Embodiment

In the fifth embodiment, a case where the rib 225 is arranged on the line 1 passing through the middle point of the side 206b, on the line m passing through the middle points of the two sides 206b and 206d, or on the side 206c has been described. In a sixth embodiment, a case where a rib 225 is arranged on a corner side of a patch 205b will be described.

In the wireless module of the sixth embodiment, the same components as those in the fifth embodiment are represented by the same reference numerals, and description thereof will not be repeated.

FIG. 21 is a plan view showing an example of an upper board 211A of a wireless module 201A according to a sixth embodiment of the present disclosure. As in the fifth embodiment, an antenna element 205 is formed on the upper board 211A. The antenna element 205 primarily includes an antenna 205A for reception and an antenna 205B for transmission. The antennas 205A and 205B respectively have four patches 205b each having four feeding points 205a. Each feeding point 205a is connected to a signal pad 205d through a feed line 205c.

Three ribs 225 are arranged on one side (in FIG. 21, the right side) in the periphery of the antenna element 205, and three ribs 225 are arranged on the other side (in FIG. 21, the left side). That is, in FIG. 21, for the 2−2 four patches 205b in the antenna 205A, four ribs 225 are arranged at symmetrical positions in the corner portions outside the respective patches 205b.

Similarly, for the 2×2 four patches 205b in the antenna 205B, four ribs 225 are arranged. The two ribs 225 at the boundary of the antennas 205A and 205B are shared for the 2×2 patches 205b in the antennas 205A and 205B.

When the ribs 225 are arranged in the corner portions outside a plurality of patches 205b, in order to maintain bonding strength of the boards, in general, it should suffice that the six ribs 225 in total are arranged at the positions shown in FIG. 21. With the use of the arrangement of the ribs 225 in FIG. 21, as the whole of the wireless module 201A, the ribs 225 are arranged with good balance. This point will be described below

FIGS. 22(A) to 22(C) are diagrams illustrating an arrangement example of the ribs 225. In FIG. 22(A), when the ribs 225 are arranged on one side (in FIG. 22(A), the left side) of the upper board 211, since one side of the wireless module 201A is pressed by the ribs 225, there is small change in thickness due to an increase in temperature. However, since the other side (in FIG. 22(A), the right side) is not pressed, change in thickness due to an increase in temperature increases. Accordingly, there is a possibility that the directionality of the antenna leans to one side.

In contrast, in FIG. 22(B), when the ribs 225 are arranged on one side (in FIG. 22(B), the left side) and the other side (in FIG. 22(B), on the left side) of the upper board 211, since both of one side and the other side are pressed by the ribs 225, there is small change in thickness due to an increase in temperature, and the thickness of the wireless module 201A is uniform.

In this way, on the upper board 211, the ribs 225 are arranged at the symmetrical positions surrounding a plurality of patches 205b, physical balance is improved, and the thickness (the thickness in the Z direction) of the wireless module 201A is made uniform. Accordingly it is possible to maintain the directionality of the antenna constant.

In this embodiment, in FIG. 21, the positional relationship between the patches 205b and the ribs 225 differs depending on the patches 205b. For this reason, while the position of the rib 225 is an electrically satisfactory position for a certain patch 205b, the position of the rib 225 may be an electrically unsatisfactory position for a different patch 205b.

If the position of the rib 225 is an electrically unsatisfactory position, a desired antenna characteristic may not be obtained. Accordingly, in the wireless module 201A, adjustment is performed to change, for example, the distance between the patches 205b depending on the position of the rib 225 and adjustment is performed to thin the shape of the patch 205b, whereby a desired antenna characteristic is obtained.

In FIG. 22(C), when the ribs 225 are arranged in the corner portions outside the 2×2 patches 205b, it is defined that the distance between the rib 225 and the corner portion outside the patch 205b: d3, the height of the patch 205b: a3, the width of the patch 205b: b3, and the patch interval: c3. When the rib 225 is on the side 206b of the patch 205b, for example, when the rib 225 is in the vicinity of the line m in FIG. 20(B), the above-described adjustment is not required.

When the rib 225 is in the corner portion outside the patch 205b, on an assumption that a3>b3, the width b3 of the patch 205b changes depending on the distance d3, that is, the shape of the patch 205b is thinned.

When the distance d3 is equal to or smaller than a predetermined value th1, the smaller the distance d3, the smaller the patch interval c3. If the distance d3 is equal to or smaller than a predetermined value th2, the smaller the distance d3, the farther (the larger) the patch interval c3. Note that th2<th1.

In this way, in the wireless module 201A, the rib 225 is arranged in the periphery of the patch 205b excluding the vicinity of the feeding point 205a, at which an electric field concentrates. The antenna element 205 has a plurality of patches 205b each having the feeding point 205a, and a plurality of ribs 225 are arranged at symmetrical positions surrounding a plurality of patches 205b. Accordingly, it is possible to prevent separation of the board of the wireless module 201A, and to perform satisfactory high-frequency communication as the whole of the wireless module 201B.

The rib 225 is arranged in the corner portion outside the patch 205b, and at least one of the shape of the patch and the interval between a plurality of patches is determined according to the distance d between the rib 225 and the corner portion. Accordingly, even when the ribs 225 are arranged at the corners outside a plurality of patches 205b, it is possible to adjust the characteristic of the antenna, and to perform satisfactory high-frequency communication.

### Seventh Embodiment

In a seventh embodiment, a case where the thickness (the thickness in the Z direction) of a wireless module is made non-uniform due to heat generation of, for example, semiconductor device (IC) mounted on a lower board 215 will be described.

The wireless module of the seventh embodiment substantially has the same configuration as in the fifth embodiment. The same components as those in the fifth embodiment are represented by the same reference numerals, and description thereof will not be repeated.

FIGS. 23(A) and 23(B) are diagrams showing a configuration example of a wireless module 201B according to the seventh embodiment of the present disclosure. FIG. 23(A) is a plan view of the wireless module 201B when viewed from the top. FIG. 23(B) shows the cross section of the wireless module 201B when viewed from a direction of an arrow E-E of FIG. 23(A).

If heat is applied due to heat generation in a semiconductor device 242 arranged on the lower board 215, the wireless module 201B thermally expands. An upper board 211B, a filling material 213, and the lower board 215 are constituted using, for example, an epoxy-based or polypropylene-based resin material. The semiconductor device 242 is primarily constituted using a silicon material.

Since the coefficient of thermal expansion of the resin material is larger than the coefficient of thermal expansion of the silicon material, in the related art, the thickness of other portions of the wireless module 201B is relatively larger than the thickness (the thickness in the Z direction) of a portion of the wireless module 201B in which the semiconductor device 242 is mounted. As a result, the thickness of the wireless module 201B may be made non-uniform, the characteristic of the antenna may be deteriorated, and unintended change in directionality may occur.

In contrast, in this embodiment, since the rib 225 is arranged on the upper board 211B directly above the position (the position within the X-Y plane) where the semiconductor device 242 is mounted, that is, at an overlapping position in the thickness direction (Z direction), the resin material on the semiconductor device 242 increases.

Accordingly, it is possible to make thermal expansion of the portion of the wireless module 201B, in which the semiconductor device 242 is mounted, conform to thermal expansion of other portions, and to maintain the thickness of the wireless module 201B constant. Accordingly, it is possible to suppress the characteristic of the antenna, and to suppress the occurrence of unintended change in directionality.

In this way, in the wireless module 201B, the rib 225 is arranged at the position of the upper board 211 overlapping the position of the electronic component (for example, the semiconductor device 242) mounted on the lower board 215 in the direction (Z direction) in which the upper board 211 and the lower board 215 face each other. Accordingly, even when an electronic component (for example, the semiconductor device 242) which is likely to generate heat is mounted on the lower board 215, it is possible to prevent separation of the board of the wireless module 201B, and to perform satisfactory high-frequency communication.

In the foregoing embodiment, although the rib 225 has a shape having the head portion, a rib may be used insofar as the rib protrudes from the rear surface of the upper board 211 or 211B and is buried in the filling material, and a pillar shape having no head portion may be used. The rib 225 may be buried in the filling material to be screwed like a pan head screw. The rib 225 is not buried in the filling material, and the upper board 211 or 211B may be simply pressed in the filling material. That is, the rib 225 may have any shape or structure insofar as movement of the upper board 211 or 211B is restricted with respect to the filling material.

(Outline of Aspects of the Present Disclosure)

A wireless module according to a first aspect of the present disclosure includes:

a first board which has a first component mounted thereon;

a second board which faces the first board and has a second component mounted thereon;

a connecting member which is provided between the first board and the second board, and transmits a signal between the first board and the second board;

a filling material with which a space between the first board and the second board including the connecting member is sealed; and

a conductive member, arranged in a periphery of the connecting member, for connecting a ground between the first board and the second board.

A wireless module according to a second aspect of the present disclosure is the wireless module according to the first aspect, wherein

the conductive member is a plurality of conductive spheres which are arranged at a plurality of positions surrounding the connecting member.

A wireless module according to a third aspect of the present disclosure is the wireless module according to the first aspect, wherein

the conductive member is a conductive tubular frame member surrounding the connecting member, and

the second board includes:

a first layer board which has the second component mounted thereon; and

a second layer board which has a wiring for transmitting a signal between the second component and the connecting member formed thereon.

A wireless module according to a fourth aspect of the present disclosure is the wireless module according to the first aspect, wherein

the conductive member is a U-shaped conductive member which surrounds the connecting member, while partly opening the periphery of the connecting member.

A wireless module according to a fifth aspect of the present disclosure is the wireless module according to the first aspect, wherein

a coaxial member is arranged between the first board and the second board, wherein the coaxial member has an inner conductor as the connecting member and an outer conductor as the conductive member which are coaxially integrated.

A wireless module according to a sixth aspect of the present disclosure is the wireless module according to the second aspect, wherein

the number of conductive spheres is at least three.

A wireless module according to a seventh aspect of the present disclosure is the wireless module according to any one of the first to sixth aspects, wherein

the first component is an antenna.

A wireless module according to an eighth aspect of the present disclosure is configured by including:

a first board which has a first electronic component and a first wiring portion mounted thereon;

a second board which faces the first board and has a second electronic component and a second wiring portion mounted thereon; and

a conductive member to which one surface of the first wiring portion and the other surface of the second wiring portion are soldered, and which electrically connects the first wiring portion and the second wiring portion, wherein

the first wiring portion has a first opening formed in a periphery of the first wiring portion,

the second wiring portion has a second opening greater than the first opening formed in a periphery of the second wiring portion, and

after melting a solder applied to the first wiring portion and the second wiring portion, a first solder connection shape formed between the first wiring portion and the conductive member is substantially equivalent to a second solder connection shape formed between the second wiring portion and the conductive member.

A wireless module according to a ninth aspect of the present disclosure is the wireless module according to the eighth aspect, wherein

the second opening has a width such that an amount of the solder which is applied to the first wiring portion, but exceeds the size of the first solder connection shape compatible with surface tension, and flows into the second wiring portion along the conductive member is receivable in the second opening.

A wireless module according to a tenth aspect of the present disclosure is the wireless module according to the eighth aspect, wherein

the first opening and the second opening are regions where a solder resist is not applied.

A wireless module according to an eleventh aspect of the present disclosure is configured by including:

a first board which has an antenna formed thereon:

a second board which faces the first board;

a filling material with which a space between the first board and the second board is filled and sealed; and

a locking member which passes through the first board and limits movement of the first board with respect to the filling material, wherein

the locking member is arranged in a periphery of the antenna excluding the vicinity of a feeding point of the antenna.

A wireless module according to a twelfth aspect of the present disclosure is the wireless module according to the eleventh aspect, wherein

the antenna has a plurality of patches each having the feeding point, and

a plurality of locking members are arranged at symmetrical positions surrounding the plurality of patches.

A wireless module according to a thirteenth aspect of the present disclosure is the wireless module according to the twelfth aspect, wherein

the locking members are arranged in corner portions outside the patches, and

at least one of the shape of the patches and the interval between the plurality of patches is determined according to a distance between the locking members and the corner portions.

A wireless module according to a fourteenth aspect of the present disclosure is the wireless module according to the eleventh aspect, wherein

the antenna has a rectangular patch having the feeding point, and

the locking member is arranged on a line which passes through a middle point of a side adjacent to a side of the rectangular patch having the feeding point formed thereon and is orthogonal to the adjacent side.

A wireless module according to a fifteenth aspect of the present disclosure is the wireless module according to the eleventh aspect, wherein

the locking member is arranged at the position of the first board overlapping the position of the electronic component mounted on the second board in a direction in which the first board and the second board face each other.

Although the present disclosure has been described in detail or referring to the specific embodiments, it is obvious to those skilled in the art that various alterations or corrections may be added without departing from the spirit and scope of the present invention.

The present application is based on Japanese Patent Application No. 2012-030896 filed on Feb. 15, 2012, Japanese Patent Application No. 2012-032186 filed on Feb. 16, 2012, and Japanese Patent Application No. 2012-032187 filed on Feb. 16, 2012, the contents of which are incorporated herein by reference.

### INDUSTRIAL APPLICABILITY

The present disclosure is useful for a wireless module which has an electronic component mounted on a board and is used in a wireless communication circuit for reducing a radiation loss of signal waves radiated from a transmission line. The present disclosure may be useful for a wireless module which has an electronic component on a board, and is able to effectively suppress impedance discontinuity of a transmission line of a signal in wireless communication. The present disclosure may be useful for a wireless module or the like which is able to prevent separation of a board of a wireless module and to allow satisfactory high-frequency communication.

### REFERENCE SIGNS LIST

1, 1A: wireless module
2, 2A: lower board
3: upper board
5, 31, 35: through-via
7: semiconductor device
8s, 8g: copper core solder ball
9: antenna
11a, 11b: feed line
12a, 12b: patch
13a, 13b: signal pad
14, 19, 33, 37: wiring pattern
15, 16, 15a: wiring pad
17, 18, 27: ground pattern
21: electronic component
25, 26: wiring pad
41, 51, 61: conductive member
71, 81: coaxial member
71a, 81a: body portion
71b: signal line
71c, 81b, 81c: conductive material
101: wireless module
105: antenna
105c: feed line
105d: signal pad
108: copper core ball
111: upper board
113: filling material
115: lower board
122: semiconductor device
131: through-via
133, 138: wiring pad
142, 144: solder fillet
151, 152: solder resist
151a, 152a: opening
161, 162: solder cream
201, 201A, 201B: wireless module
205: antenna element
205A, 205B: antenna
205a: feeding point
205b: patch
205c: feed line
205d: signal pad
206a, 206b, 206c, 206d: side
208: copper core solder ball
211, 211A, 211B: upper board
211a: pore
213: filling material
215: lower board
220: set board
223, 238: wiring pattern
225: rib
225a: head portion
231, 262: through-via
242: semiconductor device (IC)

1. A wireless module, comprising:
a first board which has a first component mounted thereon;
a second board which faces the first board and has a second component mounted thereon;
a connecting member which is provided between the first board and the second board, and transmits a signal between the first board and the second board;
a filling material with which a space between the first board and the second board including the connecting member is sealed; and
a conductive member, arranged in a periphery of the connecting member, for connecting a ground between the first board and the second board.

2. The wireless module according to claim 1, wherein
the conductive member is a plurality of conductive spheres which are arranged at a plurality of positions surrounding the connecting member.

3. The wireless module according to claim 1, wherein
the conductive member is a conductive tubular frame member surrounding the connecting member, and
the second board includes:
a first layer board which has the second component mounted thereon; and
a second layer board which has a wiring for transmitting a signal between the second component and the connecting member formed thereon.

4. The wireless module according to claim 1, wherein
the conductive member is a U-shaped conductive member which surrounds the connecting member, while partly opening the periphery of the connecting member.

5. The wireless module according to claim 1, wherein
a coaxial member is arranged between the first board and the second board, wherein the coaxial member has an inner conductor as the connecting member and an outer conductor as the conductive member which are coaxially integrated.

6. The wireless module according to claim 2, wherein the number of conductive spheres is at least three.

7. The wireless module according to claim 1, wherein
the first component is an antenna.

8. The wireless module according to claim 1, wherein
the connecting member has a same shape as that of the conductive member.
